(19) United States
(12) Patent Application Publication
(10) Pub. No.: US 2015/0156893 A1
(43) Pub. Date: Jun. 4, 2015

(54) DISPLAY DEVICE WITH IMPACT-ABSORBING MECHANISM

(71) Applicants: HON HAI PRECISION INDUSTRY CO., LTD., New Taipei (TW); Fu Tai Hua Industry (Shenzhen) Co., Ltd., Shenzhen (CN)

(72) Inventor: JIN-LONG FU, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 14/141,463

(22) Filed: Dec. 27, 2013

(30) Foreign Application Priority Data
Nov. 29, 2013 (CN) 2013106213331

(51) Int. Cl. H05K 5/00; H05K 5/02; G06F 1/16

(52) U.S. Cl. CPC H05K 5/0013; G06F 1/16; H05K 5/0217

(57) ABSTRACT

A display device includes an inner frame, a display panel, and an outer frame. The inner frame includes four first sidewalls. The display panel includes four second sidewalls respectively secured to the four first sidewalls of the inner frame. The outer frame includes four third sidewalls surrounding a support plate. The display panel is connected to the support plate. The four first sidewalls of the inner frame are spaced from the four third sidewalls of the outer frame. A number of springs are arranged between each first sidewall and the corresponding third sidewall.

### BACKGROUND

1. Technical Field

The present disclosure relates to display devices, and particularly to a display device capable of absorbing external impact.

2. Description of Related Art

Display apparatuses include a frame and a display panel directly secured in the frame. However, if an external impact is applied to the display apparatus, the external impact is directly transferred to the display panel, which may damage the display panel.

Therefore, what is needed is a means to solve the problems described above.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an isometric view of an embodiment of a display device.

FIG. 2 is an exploded, isometric view of the display device of FIG. 1.

FIG. 3 is similar to FIG. 1, but shows the display device from another perspective.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

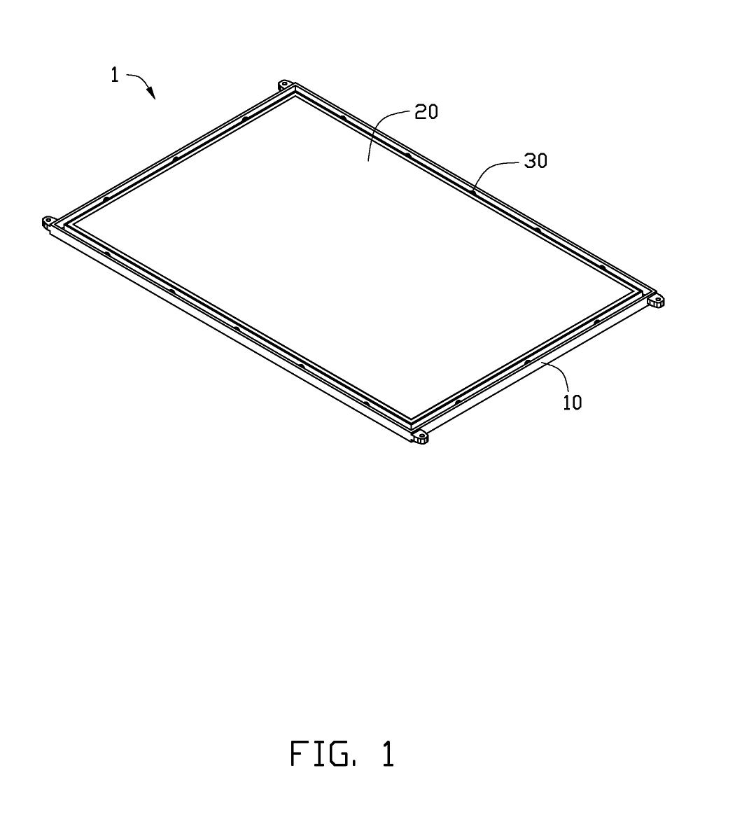

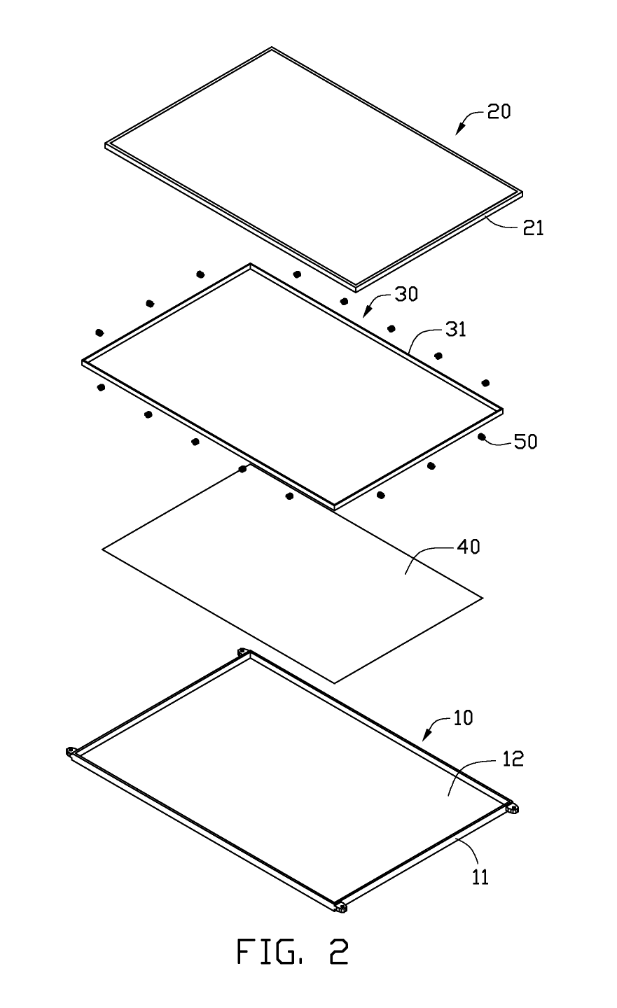

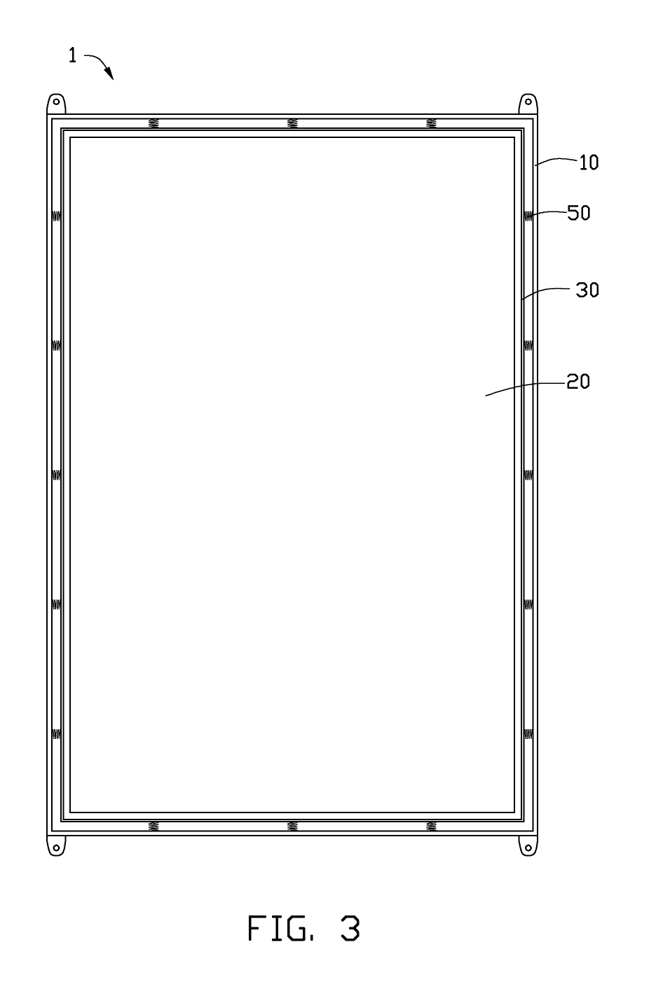

FIGS. 1-3 illustrate an exemplary embodiment of a display device 1. The display device 1 includes an outer frame 10, a display panel 20, and an inner frame 30.

In one embodiment, the inner frame 30 includes four first sidewalls 31, and the display panel 20 includes four second sidewalls 21. The four second sidewalls 21 are secured to the four first sidewalls 31, respectively, by gluing, interference fit, or other suitable securing techniques.

The outer frame 10 includes a supporting plate 12 and four third sidewalls 11 surrounding the support plate 12. The display panel 20 is adhered to the support plate 12 by an adhesive foam 40. Thus, the inner frame 30 and the display panel 20 are connected to the outer frame 10. The four first sidewalls 31 of the inner frame 30 respectively face and are spaced from the four third sidewalls 11 of the outer frame 11.

A number of springs 50 are arranged between each first sidewall 31 and the corresponding third sidewall 11. Specifically, one end of the springs 50 is fixed to the corresponding first sidewall 31, and another end of the springs 50 is fixed to the corresponding third sidewall 11 by gluing. When an external impact is applied to the display device 1, such as when the display device 1 is dropped on the ground, the springs 50 absorb some of the impact, and the inner frame 30 absorbs another portion of the impact. Thus, the display module 20 is spared from absorbing all the external impact.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A display device comprising:
an inner frame comprising four first sidewalls;
a display panel comprising four second sidewalls respectively secured to the four first sidewalls of the inner frame;
an outer frame comprising a supporting plate and four third sidewalls surrounding the support plate, the display panel connected to the support plate, the four first sidewalls of the inner frame being spaced from the four third sidewalls of the outer frame; and
a plurality of springs arranged between each first sidewall and the corresponding third sidewall.

2. The display device of claim 1, wherein the four second sidewalls are respectively secured to the four first sidewalls by one of gluing and interference fit.

3. The display device of claim 1, wherein one end of each of the plurality of springs is fixed to the corresponding first sidewall, and another end of each of the plurality of springs is fixed to the corresponding third sidewall.

4. The display device of claim 1, wherein the display panel is adhered to the support plate by an adhesive foam.
